(19) United States
(12) Patent Application Publication
(10) Pub. No.: US 2025/0219654 A1
(43) Pub. Date: Jul. 3, 2025

(54) PHASE INTERPOLATOR AND MEMORY DEVICE INCLUDING THE SAME

(71) Applicant: SAMSUNG ELECTRONICS CO., LTD., SUWON-SI (KR)

(72) Inventors: GUNWOO KONG, Suwon-si (KR); JAEHONG JUNG, Suwon-si (KR); SEUNGJIN KIM, Suwon-si (KR); JOOMYOUNG KIM, Suwon-si (KR); SEUNGHYUN OH, Suwon-si (KR); KWANGMIN LIM, Suwon-si (KR)

(21) Appl. No.: 18/915,791

(22) Filed: Oct. 15, 2024

(30) Foreign Application Priority Data
Dec. 28, 2023 (KR) 10-2023-0195419
Mar. 7, 2024 (KR) 10-2024-0032750

(51) Int. Cl. H03M 1/66

(52) U.S. Cl. CPC H03M 1/661; H03M 1/662

(57) ABSTRACT

A phase interpolator providing a pair of differential outputs according to a plurality of inputs with a plurality of phases, the phase interpolator including: a main digital-to-analog converter (DAC) circuit configured to phase-interpolate a first input and a second input, which have orthogonal phases among the plurality of inputs, according to a main code to generate a main output signal; an auxiliary DAC circuit configured to phase-interpolate the first input and the second input according to an auxiliary code corresponding to the main code to generate an auxiliary output signal; and an output buffer configured to generate the pair of differential outputs according to a differential input based on a phase output signal, which is the sum of the main output signal and the auxiliary output signal.

### CROSS-REFERENCE TO RELATED APPLICATIONS

This application claims priority under 35 U.S.C. § 119 to Korean Patent Application No. 10-2023-0195419 filed in the Korean Intellectual Property Office on Dec. 28, 2023, and Korean Patent Application No. 10-2024-0032750 filed in the Korean Intellectual Property Office on Mar. 7, 2024, the disclosures of which are incorporated by reference herein in their entireties.

### (A) TECHNICAL FIELD

The disclosure relates to a phase interpolator and a memory device including the same.

### (B) DESCRIPTION OF THE RELATED ART

A register clock driver (RCD) integrated circuit (IC) for driving memory devices requires a 1/64-step phase interpolation function, as specified by the Joint Electron Device Engineering Council (JEDEC) standard, to achieve optimal timing control between memory devices. To support a data processing rate of 7.2 Gbps at double-data rate (DDR)5, the RCD should provide a phase interpolation function with highly linear characteristics at clock frequencies up to 3.6 GHz. Multiple phase interpolators are necessary to support memory devices, and current mode phase interpolators are typically used to avoid inter-power interference and frequency pulling.

However, because the current mode phase interpolator adjusts the current output of a digital-analog converter (DAC) using a first-order linear code, significant phase and amplitude errors can occur during the interpolation process at the current mode logic (CML) level. Furthermore, these amplitude errors can lead to amplitude modulation-to-phase modulation (AM-to-PM) distortion when converting an output signal from the CML level to a complementary metal oxide semiconductor (CMOS) level. This AM-to-PM distortion can degrade the linear characteristics of the current mode phase interpolator.

### SUMMARY

The disclosure provides a phase insulator and a memory device including the same, capable of minimizing phase and amplitude errors in a current mode logic (CML)-level phase interpolation process.

According to an embodiment of the disclosure, there is provided a phase interpolator providing a pair of differential outputs according to a plurality of inputs with a plurality of phases, the phase interpolator including: a main digital-to-analog converter (DAC) circuit configured to phase-interpolate a first input and a second input, which have orthogonal phases among the plurality of inputs, according to a main code to generate a main output signal; an auxiliary DAC circuit configured to phase-interpolate the first input and the second input according to an auxiliary code corresponding to the main code to generate an auxiliary output signal; and an output buffer configured to generate the pair of differential outputs according to a differential input based on a phase output signal, which is the sum of the main output signal and the auxiliary output signal.

According to an embodiment of the disclosure, there is provided a phase interpolator including: a main DAC circuit configured to provide, to a first node, a first phase current based on a first input with a first weight and a second phase current based on a second input, orthogonal to the first input, with a second weight; an auxiliary DAC circuit configured to provide a third phase current based on the first input and a fourth phase current based on the second input, with a third weight, to the first node; an output buffer configured to generate an output signal based on a voltage of the first node; and an auxiliary DAC controller configured to determine the third weight based on an auxiliary code that corresponds to a main code indicating the first weight and the second weight.

According to an embodiment of the disclosure, there is provided a memory device including: a plurality of memory modules; and a phase interpolator configured to buffer a command, an address, and a clock signal provided from an external source and transmit the buffered command, address, and clock signal to the plurality of memory modules, wherein the phase interpolator includes: a main DAC circuit configured to phase-interpolate a first input and a second input, which have orthogonal phases, representing each of the command, the address, and the clock signal based on a main code to generate a main output signal; an auxiliary DAC circuit configured to phase-interpolate the first input and the second input based on an auxiliary code corresponding to the main code to generate an auxiliary output signal; and an output buffer generating a pair of differential outputs according to a differential input based on a phase output signal, which is the sum of the main output signal and the auxiliary output signal.

The phase insulator and the memory device incorporating it are designed to minimize phase and amplitude errors in a current mode logic (CML)-level phase interpolation process. By improving the linearity of the phase interpolator, the memory device can capture data with optimal timing.

### BRIEF DESCRIPTION OF THE DRAWINGS

FIG. 1 is a block diagram showing an electronic device according to an embodiment of the disclosure.

FIG. 2 is a diagram showing a register clock driver according to an embodiment of the disclosure.

FIG. 3 is a block diagram showing a configuration of a main digital-to-analog converter (DAC) circuit according to an embodiment of the disclosure.

FIG. 4 is a phase constellation for a main output signal of a main DAC circuit according to an embodiment of the disclosure.

FIG. 5 is a block diagram showing a configuration of an auxiliary DAC circuit according to an embodiment of the disclosure.

FIG. 6 is a phase constellation for a phase output signal according to an embodiment of the disclosure.

FIG. 7 is a diagram showing a first quadrant of a phase constellation of a main output signal and a phase output signal according to an embodiment of the disclosure.

FIG. 8 is a circuit diagram showing one of a plurality of main DAC circuits according to an embodiment of the disclosure.

FIG. 9 is a circuit diagram showing one of a plurality of auxiliary DAC circuits according to an embodiment of the disclosure.

FIG. 10 is a circuit diagram showing one of a plurality of auxiliary DAC circuits according to an embodiment of the disclosure.

FIGS. 11A and 11B are graphs showing improved integral non-linearity with the addition of an auxiliary DAC circuit.

FIGS. 12A and 12B are graphs showing improved differential linearity with the addition of an auxiliary DAC circuit.

FIGS. 13A and 13B are graphs showing improved amplitude and amplitude modulation-to-phase modulation (AM-to-PM) distortion of a phase output signal with the addition of an auxiliary DAC circuit.

### DETAILED DESCRIPTION OF THE EMBODIMENTS

This disclosure relates to phase and amplitude compensation for improving the linearity of a current mode phase interpolator. Some embodiments of the disclosure may include a main digital-to-analog converter (DAC) circuit and an auxiliary DAC circuit that adjust the current output of a current mode phase interpolator. In response to a main code controlling the current output of the main DAC circuit, the auxiliary DAC circuit may control additional current output. Through this approach, the output current of the current mode phase interpolator can be adjusted to a target current. The target current is a current that has the required phase and amplitude according to the main code.

In the following specification, a signal level may be defined as either a current mode logic (CML) level or a complementary metal oxide semiconductor (CMOS) level. Each of the CML level and the CMOS level corresponds to a signal having a specific amplitude based on a corresponding DC level. The reference DC level and amplitude of the CML level are smaller than those of the CMOS level.

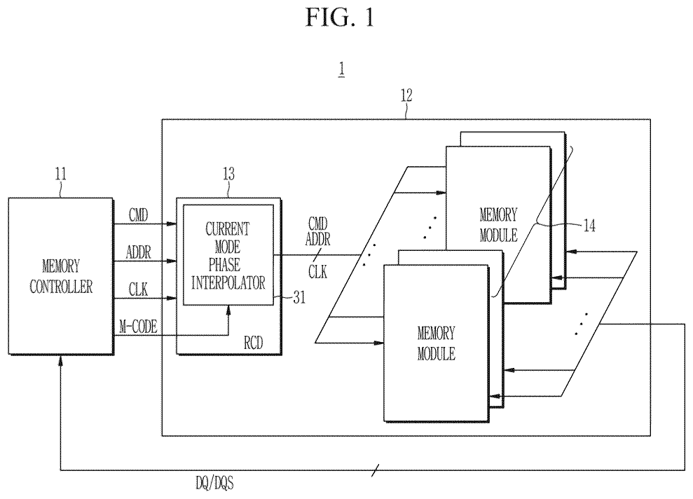

FIG. 1 is a block diagram showing an electronic device according to an embodiment of the disclosure.

The electronic device 1 may include a memory controller 11 and a memory device 12. For example, the electronic device 1 may be or may be included in a mobile system, such as a mobile phone, a smartphone, a tablet personal computer, a wearable device, a healthcare device, or an Internet of things (IOT) device. The electronic device 1 may be or may be included in an automotive device, such as a personal computer, laptop computer, server, media player, or navigation device.

The memory controller 11 may be configured to store data in the memory device 12 or read data stored in the memory device 12. For example, the memory controller 11 may transmit a command CMD, an address ADDR, and a clock signal CLK to the memory device 12. In some embodiments, the memory controller 11 may be or may be included in a system-on-chip (SoC). The memory controller 11 may generate a command CMD and an address ADDR for the memory device 12 in response to a request from an internal processor of a host. The memory device 12 may operate as a buffer memory, working memory, or main memory for the host. The host may include the memory controller 11 or may be a higher-level controller for the memory controller 11.

The memory device 12 may operate under the control of the memory controller 11. In response to the command CMD, address ADDR, and clock signal CLK received from the memory controller 11, the memory device 12 may store data received through a data signal DQ and a data strobe signal DQS or output data stored in the memory device 12 to the memory controller 11 through the data signal DQ and the data strobe signal DQS.

The memory device 12 may include a register clock driver 13 including a phase interpolator and a plurality of memory modules 14. Each of the memory modules 14 may be a dynamic random access memory (DRAM) device. However, the scope of the disclosure is not limited thereto. In response to the command CMD, address ADDR, and clock signal CLK provided through the register clock driver 13, the plurality of memory modules 14 may write data received through the data signal DQ and the data strobe signal DQS to the plurality of memory modules 14 or output data stored in the plurality of memory modules 14 to the memory controller 11 through the data signal DQ and the data strobe signal DQS.

The register clock driver 13 may be connected to a plurality of memory modules 14 and drive the plurality of memory modules 14. The register clock driver 13 may include a phase interpolator 31. The phase interpolator 31 may be implemented as a current mode phase interpolator. The register clock driver 13 may receive the command CMD, address ADDR, and clock signal CLK from the memory controller 11 using the current mode phase interpolator 31, buffer the command CMD, address ADDR, and clock signal CLK and transmit the buffered command CMD, address ADDR, and clock signal CLK to the plurality of memory modules 14.

In controlling the buffering of the register clock driver 13, phase interpolation may be provided. Phase interpolation refers to generating an input with a certain phase between two mutually orthogonal phases using two mutually orthogonal phase signals. The register clock driver 13 may provide phase interpolation for each of the command CMD, address ADDR, and clock signal CLK. The register clock driver 13 may include a current mode phase interpolator 31 that provides phase interpolation. An output signal of the current mode phase interpolator 31 may be a differential signal with inverted phases.

The current mode phase interpolator 31 may generate a differential input through phase interpolation using two phase signals orthogonal to each other under the control of the register clock driver 13 and generate a differential signal according to the differential input. The current mode phase interpolator 31 may generate a plurality of phase currents to generate a differential input at the voltage level. The sum of phase currents corresponding to the same phase signal among the plurality of phase currents is referred to as an output signal (hereinafter, a phase output signal) of the corresponding phase.

A positive input among differential inputs is determined by the combination of two phase output signals corresponding to each of the two mutually orthogonal phase signals, and a negative input among the differential inputs may be determined by the combination of two inverted phase output signals corresponding to each of two inverted phase signals of the two mutually orthogonal phase signals.

In the following specification, phase interpolation using two phase signals orthogonal to each other is described.

The memory controller 11 may provide the current mode phase interpolator 31 with a main code (M-CODE) to control the phase interpolation of the main DAC circuit 130. The current mode phase interpolator 31 may determine an auxiliary code (A-CODE) corresponding to the M-CODE to control the phase interpolation of the auxiliary DAC circuit 140. The phase interpolation of the current mode phase interpolator 31 can then be controlled according to both the M-CODE and A-CODE. The current mode phase interpolator 31 may generate a differential input by combining the phase interpolation according to the M-CODE with the phase interpolation according to the A-CODE, and subsequently generate a differential output based on the differential input. The differential output may indicate the command CMD, the address ADDR, and the clock signal CLK received by the memory device 12.

The memory controller 11 may perform training to determine the M-CODE. During this training, the memory controller 11 may sample output signals of the current mode phase interpolator 31, while changing the M-CODE. The M-CODE at which the sampled output signals reach an optimal level can then be determined.

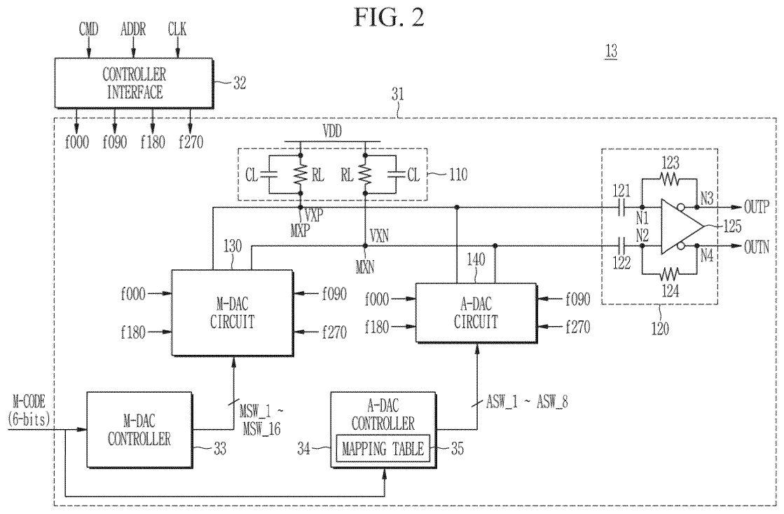

FIG. 2 is a diagram showing a register clock driver according to an embodiment of the disclosure.

As shown in FIG. 2, the register clock driver 13 may include a current mode phase interpolator 31 and a controller interface 32. The current mode phase interpolator 31 may include a main DAC controller 33, a mapping table 35, an auxiliary DAC controller 34, a load circuit 110, an output buffer 120, a main DAC circuit (M-DAC CIRCUIT) 130, and an auxiliary DAC circuit (A-DAC CIRCUIT) 140).

The controller interface 32 may generate phase signals f000, f090, f180, and f270 for each of the command CMD, address ADDR, and clock signal CLK provided from the memory controller 11. Each of the phase signals f000, f090, f180, and f270 may correspond to respective phases of 0 degrees, 90 degrees, 180 degrees, and 270 degrees. For example, the phase of the phase signal f000 may be 0 degrees, the phase of the phase signal f090 may be 90 degrees, the phase of the phase signal f180 may be 180 degrees, and the phase of the phase signal f270 may be 270 degrees. The phase signals f000, f090, f180, and f270 may be provided as input signals to the main DAC circuit 130 and the auxiliary DAC circuit 140.

The main DAC controller 33 may control the phase interpolation of the main DAC circuit 130 according to the M-CODE. The main DAC controller 33 may select two orthogonal phase signals from the phase signals f000, f090, f180, and f270 based on the M-CODE and determine the respective weights for each of the selected phase signals. The M-CODE may include a phase region code, indicating which two orthogonal phase signals to select from the four phase signals f000, f090, f180, and f270, and a phase control code, specifying the weights for each of the two orthogonal phase signals. Utilizing the phase region code of the M-CODE, the main DAC controller 33 may select the two orthogonal phase signals and generate a plurality of main control signals MSW_1 to MSW_16 to control the phase interpolation of the main DAC circuit 130 based on the two weights provided by the phase control code.

A phase region defined by the two orthogonal phase signals, selected from the four phase signals f000, f090, f180, and f270, may correspond to one of a first quadrant of 0 to 90 degrees, a second quadrant of 180 to 90 degrees, a third quadrant of 180 to 270 degrees, and a fourth quadrant of 0 to 270 degrees. The main DAC circuit 130 shown in FIG. 2 may include 16 DACs. To control the phase output signals of the 16 DACs, the main DAC controller 33 may generate the plurality of main control signals MSW_1 to MSW_16. The number of main control signals MSW_1 to MSW_16 depends on the number of DACs constituting the main DAC circuit 130, but the number of DACs and the number of main control signals are not limited thereto.

The auxiliary DAC controller 34 may control the phase interpolation of the auxiliary DAC circuit 140 based on the M-CODE. The auxiliary DAC controller 34 may determine an A-CODE that specifies the weights for each of the two orthogonal phase signals selected from the phase signals f000, f090, f180, and f270 according to the M-CODE. The auxiliary DAC controller 34 may generate a plurality of auxiliary control signals ASW_1 to ASW_8 based on the two weights. The number of auxiliary control signals ASW_1 to ASW_8 depends on the number of DACs constituting the auxiliary DAC circuit 140, and the number of DACs and the number of auxiliary control signals are not limited thereto.

The load circuit 110 is connected between a power supply voltage VDD and two nodes MXP and MXN. A main output signal of the main DAC circuit 130 and an auxiliary output signal of the auxiliary DAC circuit 140 converge in the load circuit 110. A voltage (a first output voltage VXP) at the node MXP is determined by the voltage drop in the load circuit 110, caused by the main output signal and the auxiliary output signal flowing between the node MXP and the power supply voltage VDD. A voltage (a second output voltage VXN) of the node MXN is determined by the voltage drop in the load circuit 110, caused by the main output signal and the auxiliary output signal flowing between the node MXN and the power supply voltage VDD. The load circuit 110 includes a resistor RL connected between the power supply voltage VDD and the node MXP and another resistor RL connected between the power supply voltage VDD and the node MXN. In FIG. 2, two capacitors CL are connected in parallel in the load circuit 110. These two capacitors CL may form a capacitor bank that performs harmonic filtering for each band, thereby supporting a wide frequency band for each of the first and second output voltages VXP and VXN.

The output buffer 120 may generate two output signals OUTP and OUTN having a CMOS level by inverting the first and second output voltages VXP and VXN having a CML level, respectively. The output buffer 120 may include two capacitors 121 and 122, two resistors 123 and 124, and an inverter 125. The capacitor 121 may provide AC coupling between the node MXP and an input node N1, filtering out the DC component of the first output voltage VXP. The capacitor 122 may provide AC coupling between the node MXN and an input node N2, filtering out the DC component of the second output voltage VXN. The resistor 123 may be connected between an output node N3 and the input node N1 of the inverter 125, feeding back an output signal OUTP to the input node N1. The resistor 124 may be connected between the output node N4 and the input node N2 of the inverter 125, feeding back an output signal OUTN to the input node N2.

The output buffer 120 may invert the first output signal VXP having the CML level to generate an output signal OUTP with the CMOS level and invert the second output signal VXN having the CML level to generate an output signal OUTN with the CMOS level. The first output signal OUTP and the second output signal OUTN may be differential outputs representing the command CMD, address ADDR, and clock signal CLK input to the register clock driver 31.

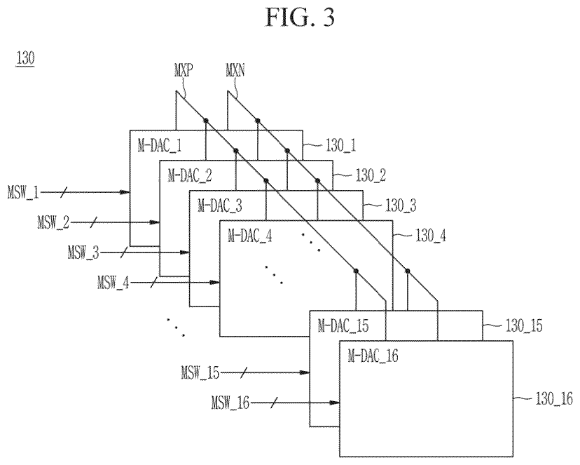

FIG. 3 is a block diagram showing a configuration of a main DAC circuit according to an embodiment of the disclosure.

As shown in FIG. 3, the main DAC circuit 130 may include 16 DACs M-DAC_1 to M-DAC_16 (130_1 to 130_16). Each of M-DAC_1 to M-DAC_16 (130_1 to 130_16) may provide a phase current flowing from the two nodes MXP and MXN to each of M-DAC_1 to M-DAC_16 (130_1 to 130_16) according to each of the plurality of main control signals MSW_1 to MSW_16. The main DAC circuit 130 may provide two main output signals for each of the two nodes MXP and MXN. One of the two main output signals may be the sum of the phase currents flowing from the node MXP to M-DAC_1 to M-DAC_16 (130_1 to 130_16), while the other may be the sum of the phase currents flowing from the node MXN to M-DAC_1 to M-DAC_16 (130_1 to 130_16).

The phases of the voltages at the nodes MXP and MXN, which are the phases of the differential inputs, may be controlled according to the phase currents of M-DAC_1 to M-DAC_16 (130_1 to 130_16). Each of M-DAC_1 to M-DAC_16 (130_1 to 130_16) may control the phase currents from the two nodes MXP and MXN based on one of the two orthogonal phase signals, as determined by the corresponding main control signals MSW_1 to MSW_16. An ON-OFF level combination of each of the plurality of main control signals MSW_1 to MSW_16 may vary depending on the weight of each of the two orthogonal phase signals. Each of the plurality of main control signals MSW_1 to MSW_16 may include a plurality of switching signals, with each of the plurality of switching signals being at either an ON level and an OFF level. The ON-OFF level combination of each main control signal refers to a combination of the ON and OFF levels of a plurality of switching signals.

1/64 interval phase interpolation provided by the main DAC circuit 130, according to some embodiments, utilizes two orthogonal phase signals from the four phase signals f000, f090, f180, and f270 having phases of 0 degrees, 90 degrees, 180 degrees, and 270 degrees. Specifically, the available combinations of two orthogonal phase signals may include (0°,90°), (180°,90°), (180°,270°), and (0°,270°). The main DAC circuit 130 may generate a main output signal V_{PI}[n] by combining two orthogonal phase signals sin(2πft) and cos(2πft) into a first-order linear sum as shown in Equation 1. By adjusting weights w₁[n] and w_{Q}[n] of these two orthogonal phase signals in 1/16 intervals, the main DAC circuit 130 may generate n-th phase current V_{PI}[n], interpolated between two orthogonal phase signals. Therefore, the main DAC circuit 130 may achieve phase interpolation at 1/64 intervals between 0° and 360°.

$${V}_{PI} [ n ] = {w}_{I} [ n ] \times sin ( 2 π ft ) + {w}_{Q} [ n ] \times cos ( 2 π ft ) = \sqrt{{{w}_{I} [ n ]}^{2} + {{w}_{Q} [ n ]}^{2}} \times sin [ 2 πft + arctan ( \frac{{w}_{Q} [ n ]}{{w}_{I} [ n ]} ) ] = {A}_{PI} [ n ] sin ( 2 π ft + {ϕ}_{PI} [ n ] ) \qquad [ Equation 1 ]$$

In Equation 1, the two phase signals sin(2πft) and cos(2πft) orthogonal to each other are sinusoidal signals. For the main output signal V_{PI}[n] to have a constant amplitude and be phase-interpolated at regular intervals, the weights w_{I}[n] and w_{Q}[n] should have an orthogonal sinusoidal relationship as

$${w}_{I} [ n ] = K cos ( \frac{n}{64} \times 2 π ) , {w}_{Q} [ n ] = K sin ( \frac{n}{64} \times 2 π ) ,$$

respectively. In Equation 1,

$${A}_{PI} [ n ] = K , {ϕ}_{PI} [ n ] = \frac{n}{64} \times 2 π$$

and K=constant.

However, implementing weights with an orthogonal sinusoidal relationship requires a high-resolution current DAC, which increase circuit size due to high implementation complexity. To lower the resolution of the current DAC, the current mode phase interpolator 31 may interpolate the phase using two weights w_{I}[n]+w_{Q}[n]=K such that their first-order linear sum is constant.

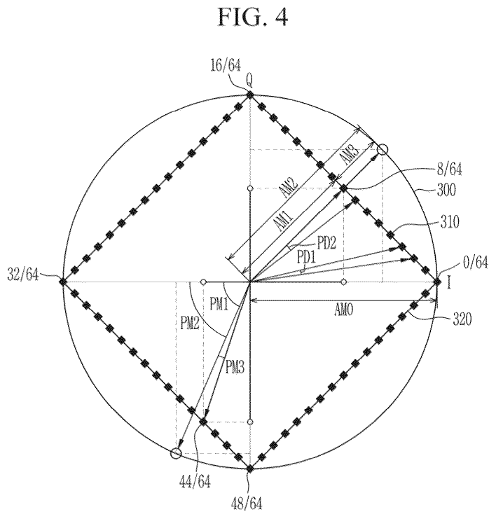

FIG. 4 is a phase constellation for a main output signal of a main DAC circuit according to an embodiment of the disclosure.

The phase constellation of FIG. 4 follows horizontal and vertical coordinate systems, respectively indicating the I and Q signals that constitute the main output signal. In this phase constellation, points (referred to as “output points”), such as point 310, indicate the phase and amplitude of the main output signal for each of the 64 codes, forming a diamond shape 320. When the main DAC circuit 130 generates the main output signal through phase interpolation using two weights whose first-order linear sum is constant, the phase constellation 320 of the main output signal has a diamond shape.

As shown in FIG. 4, there is a phase or/and amplitude difference between the phase constellation 320 and a circle 300 for each of the 64 codes. The circle 300 represents the phase constellation when the main output signal is generated with constant amplitude and constant phase intervals. For example, during the 8/64 phase interpolation step in the first quadrant, the maximum amplitude difference AM3 occurs between the amplitude of a main output signal AM1 and a corresponding reference amplitude AM2 on the circle 300. During the 44/64 phase interpolation step in the third quadrant, the maximum phase difference PM3 occurs between a phase PM1 of the main output signal and a corresponding reference phase PM2 on the circle 300.

When the first-order linear sum of the two weights for each code is constant, as shown in FIG. 4, the phase differences (e.g., PD1, PD2) between the main output signals for each code are not constant. This inconsistency results in a large differential non-linearity (DNL) and a large integral non-linearity (INL) with respect to the phase of the main output signal. In addition, an amplitude variation (e.g., AM0-AM1) of the main output signal for each code is large, leading to AM-to-PM distortion as the output signal at the CML level passes through the output buffer 120 for conversion to the CMOS level.

The current mode phase interpolator 31 according to some embodiments may further include an auxiliary DAC circuit 140 that provides each of two additional auxiliary weights to each of the two weights to improve the linearity of the main DAC circuit 130.

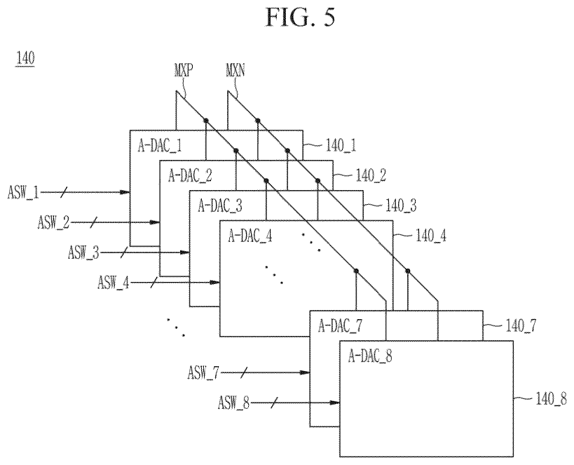

FIG. 5 is a block diagram showing a configuration of an auxiliary DAC circuit according to an embodiment of the disclosure.

As shown in FIG. 5, the auxiliary DAC circuit 140 may include eight DACs, A-DAC_1 to A-DAC_8 (140_1 to 140_8). Each of A-DAC_1 to A-DAC_8 (140_1 to 140_8) may provide phase currents flowing respectively from the two nodes MXP and MXN to A-DAC_1 to A-DAC_8 (140_1 to 140_8) according to a plurality of auxiliary control signals ASW_1 to ASW_8. The auxiliary DAC circuit 140 may provide two auxiliary output signals for each of the two nodes MXP and MXN. One of the two auxiliary output signals may be the sum of the phase currents flowing from the node MXP to A-DAC_1 to A-DAC_8 (140_1 to 140_8) and the other may be the sum of the phase currents flowing from the node MXN to A-DAC_1 to A-DAC_8 (140_1 to 140_8).

The voltage phases at nodes MXP and MXN, representing the phases of the differential inputs, may be controlled according to the phase currents of A-DAC_1 to A-DAC_8 (140_1 to 140_8). Each of A-DAC_1 to A-DAC_8 (140_1 to 140_8) may control the phase currents from the two nodes MXP and MXN based on one of two orthogonal phase signals, as determined by the corresponding auxiliary control signals ASW_1 to ASW_8. An ON-OFF level combination of each of the plurality of auxiliary control signals ASW_1 to ASW_8 may vary depending on the weight of each of the two orthogonal phase signals. Each of the plurality of auxiliary control signals ASW_1 to ASW_8 may include a plurality of switching signals, with each switching signal being at either an ON level or an OFF level. The ON-OFF level combination of each auxiliary control signal refers to a combination of the ON levels and OFF levels of the plurality of switching signals.

For each of the two nodes MXP and MXN, when the auxiliary output signal provided by the auxiliary DAC circuit 140 is added to the main output signal provided by the main DAC circuit 130, a phase output signal having a phase constellation close to the circle 300 of FIG. 4 may be provided.

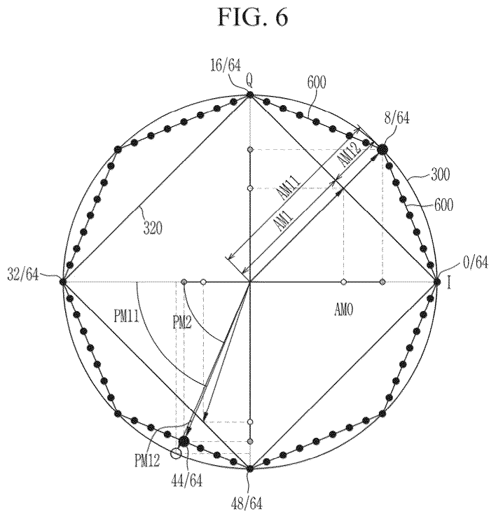

FIG. 6 is a phase constellation for a phase output signal according to an embodiment of the disclosure.

The phase constellation of FIG. 6 follows the horizontal and vertical coordinate systems indicating, the I and Q signals that make up the phase output signal. This constellation, showing 64 output points (e.g., 610) for each code, is depicted as an octagon. The phase constellation 600, where the auxiliary output signal is superimposed on the main output signal, more closely resembles the circle 300 than the phase constellation 320 shown in FIG. 4.

As shown in FIG. 6, the phase and/or amplitude difference between the phase constellation 600 and the circle 300 for each of the 64 codes is smaller than the phase and/or amplitude difference shown in FIG. 4. For example, in the phase interpolation step 8/64 of the first quadrant, an amplitude AM11 of the phase output signal is equal to a corresponding reference amplitude AM11 in the circle 300. The amplitude AM11 of the phase output signal is achieved by adding an amplitude AM12 of the auxiliary output signal to the amplitude AM1 of the main output signal. In the phase interpolation step 44/64 of the third quadrant, the phase difference PM12 between the phase PM11 of the main output signal and the corresponding reference phase PM2 in the circle 300 is significantly reduced than the phase difference PM3 in FIG. 4.

Consequently, the phase constellation 600 in FIG. 6 shows a reduced phase difference between phase output signals for each code, leading to decreased differential non-linearity (DNL) and integral non-linearity (INL) with respect to the phases of the phase output signals. In addition, the amplitude variation of the phase output signal for each code is reduced, thereby reducing AM-to-PM distortion as the output signal, having the CML level, passes through the buffer for conversion to the CMOS level.

To control the phase and amplitude of the auxiliary output signal for each of the 64 M-CODE codes, the auxiliary DAC controller 34 may select the corresponding A-CODE for each M-CODE. The auxiliary DAC controller 34 may generate a plurality of auxiliary control signals ASW_1 to ASW_8 based on the weight of each of the two orthogonal phase signals according to the A-CODE and provide these signals to the auxiliary DAC circuit 140. The A-CODE corresponding to each M-CODE may be set as shown in Tables 1 to 4 below and stored in a mapping table 35.

First, Table 1 shows the M-CODE and the corresponding A-CODE, which indicate phase interpolation using two orthogonal phase signals, f000 and f090 among the plurality of phase signals f000, f090, f180, and f270. The phase output signal generated using the two phase signals f000 and f090 according to M-CODE and A-CODE is located in the first quadrant's phase region.

TABLE 1

| | M-CODE | | | | | | | | | | |
|---|---|---|---|---|---|---|---|---|---|---|---|
| STEP | MSB | LSB | | Main DAC code | | | | Auxiliary DAC code | | | |
| INDEX | <1:0> | <3:0> | A-CODE | 0° | 90° | 180° | 270° | 0° | 90° | 180° | 270° |
| 0 | 00 | 0000 | 0000 | 16 | 0 | 0 | 0 | 0 | 0 | 0 | 0 |
| 1 | 00 | 0001 | 0001 | 15 | 1 | 0 | 0 | 1 | 1 | 0 | 0 |
| 2 | 00 | 0010 | 0010 | 14 | 2 | 0 | 0 | 2 | 2 | 0 | 0 |
| 3 | 00 | 0011 | 0011 | 13 | 3 | 0 | 0 | 3 | 3 | 0 | 0 |
| 4 | 00 | 0100 | 0100 | 12 | 4 | 0 | 0 | 4 | 4 | 0 | 0 |
| 5 | 00 | 0101 | 0101 | 11 | 5 | 0 | 0 | 5 | 5 | 0 | 0 |
| 6 | 00 | 0110 | 0110 | 10 | 6 | 0 | 0 | 6 | 6 | 0 | 0 |
| 7 | 00 | 0111 | 0111 | 9 | 7 | 0 | 0 | 7 | 7 | 0 | 0 |
| 8 | 00 | 1000 | 1000 | 8 | 8 | 0 | 0 | 8 | 8 | 0 | 0 |
| 9 | 00 | 1001 | 0111 | 7 | 9 | 0 | 0 | 7 | 7 | 0 | 0 |
| 10 | 00 | 1010 | 0110 | 6 | 10 | 0 | 0 | 6 | 6 | 0 | 0 |
| 11 | 00 | 1011 | 0101 | 5 | 11 | 0 | 0 | 5 | 5 | 0 | 0 |
| 12 | 00 | 1100 | 0100 | 4 | 12 | 0 | 0 | 4 | 4 | 0 | 0 |
| 13 | 00 | 1101 | 0011 | 3 | 13 | 0 | 0 | 3 | 3 | 0 | 0 |
| 14 | 00 | 1110 | 0010 | 2 | 14 | 0 | 0 | 2 | 2 | 0 | 0 |
| 15 | 00 | 1111 | 0001 | 1 | 15 | 0 | 0 | 1 | 1 | 0 | 0 |

In Table 1, M-CODE may be a 6-bit signal. The upper 2 bits of the M-CODE, MSB<1:0>, are phase region codes that indicate which two orthogonal phase signals will be used for phase interpolation. The main DAC controller 33 may determine the two orthogonal phase signals for the main DAC circuit 130 based on the phase region code. The lower 4 bits of the M-CODE, LSB<3:0>, are a phase control code indicating the weight of each of the two orthogonal phase signals I and Q signals, which make up the main output signal. The weight of the I signal reflects the number of phase currents corresponding to the I signal, while the weight of the Q signal reflects the number of phase currents corresponding to the Q signal. Depending on the LSB<3:0> value, the weight of the I signal and the weight of the Q signal in the corresponding quadrant may be set. “Main DAC code” may indicate the number of phase currents provided by the main DAC circuit 130 for each phase. “Auxiliary DAC code” may indicate the number of phase currents provided by the auxiliary DAC circuit 140 for each phase.

As can be seen in Table 1, MSB<1:0> “00” indicates the first quadrant, where 16 codes from 0 to 15 represent phase interpolation in the first quadrant. In the first quadrant, the I signal may be in phase at 0 degrees, and the Q signal may be in phase at 90 degrees. LSB<3:0> “0000” in the first quadrant represents the maximum weight of the I signal and the minimum weight of the Q signal. As the LSB<3:0> value increases, the weight of the I signal may decrease and the weight of the Q signal may increase. LSB<3:0> “1111” in the first quadrant represents the minimum weight of the I signal and the maximum weight of the Q signal. In the first quadrant, according to LSB<3:0> “0000”, the main DAC controller 33 may control the main DAC circuit 130 to provide 16 zero degree phase currents. In the first quadrant, according to LSB<3:0>“0001”, the main DAC controller 33 may control the main DAC circuit 130 to provide 15 phase currents for the 0 degree phase and 1 phase current for the 90 degree phase. In the first quadrant, according to LSB<3:0> “1111”, the main DAC controller 33 may control the main DAC circuit 130 to provide 1 phase current for the 0 degree phase and 15 phase currents for the 90 degree phase.

The auxiliary DAC controller 34 may determine two orthogonal phase signals to be used by the auxiliary DAC circuit 140 according to the phase region code. For example, when MSB<1:0> is “00,” the auxiliary DAC controller 34 may select the orthogonal phase signals f000 and f090. The auxiliary DAC controller 34 may determine the A-CODE according to the phase control code LSB<3:0>. In the range “0000” to “1000” of the phase control code LSB<3:0>, the auxiliary DAC controller 34 may determine the A-CODE to be larger since the phase control code LSB<3:0> is larger according to the mapping table 35 implemented as shown in Table 1. Then, since the phase control code LSB<3:0> is larger, the weights of the I signal and the Q signal constituting the auxiliary output signal are large. In the range “1001” to “1111” of the phase control code LSB<3:0>, the auxiliary DAC controller 34 may determine the A-CODE to be smaller since the phase control code LSB <3:0> is larger according to the mapping table 35 implemented as shown in Table 1. Then, since the phase control code LSB<3:0> is larger, the weights of the I signal and the Q signal constituting the auxiliary output signal are small.

In the first quadrant, between the 0 degree phase and the 90 degree phase indicated by the upper 2 bits MSB<0:0> of the M-CODE, the auxiliary DAC controller 34 may determine that the weight of the I signal and the weight of the Q signal in the auxiliary output signal have the largest value when the M-CODE includes LSB<3:0>“1000”, indicating the midpoint between 0 degrees and 90 degrees, e.g. 45 degrees. The auxiliary DAC controller 34 may determine the auxiliary code so that the weight of the I signal and the weight of the Q signal of the auxiliary output signal decrease as the phase indicated by the M-CODE moves away from 45 degrees. Thus, when the auxiliary DAC circuit 140 provides phase interpolation according to the A-CODE based on the M-CODE, as shown in FIG. 6, the phase constellation 600 of the phase output current may form an octagon.

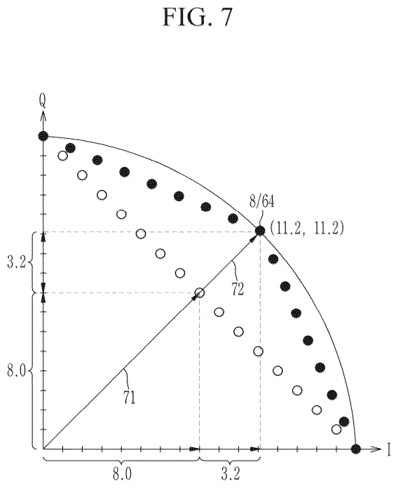

FIG. 7 is a diagram showing the first quadrant of a phase constellation of a main output signal and a phase output signal according to an embodiment of the disclosure.

In FIG. 7, a main output signal, an auxiliary output signal, and a phase output signal are quantified using arbitrary units. In other words, the magnitude of each of the I signal and the Q signal for each signal may be expressed numerically, such as “8” and “3.2” in arbitrary units.

According to M-CODE “001000”, the main DAC circuit 130 may provide a main output signal interpolated at 8/64 steps, corresponding to a phase of 45°. The main DAC circuit 130 may generate the sum of phase currents for the I signal at 0 degrees and the Q signal at 90 degrees, both as “8”. According to the A-CODE “1000”, which corresponds to the M-CODE “001000”, the auxiliary DAC circuit 140 may provide an auxiliary output signal also interpolated at 8/64 steps, with a phase of 45°. The auxiliary DAC circuit 140 may generate the sum of phase currents for the I signal at 0 degrees and the Q signal at 90 degrees, both as “3.2”.

Then, as shown in FIG. 7, an amplitude attenuation of the phase output signal may be minimized. According to a vector sum of the main output signal 71 of (8, 8) and the auxiliary output signal 72 of (3.2, 3.2), the phase output signal has a phase and amplitude of (11.2, 11.2). The amplitude of the phase output signal of (11.2, 11.2) is approximately 15.84, and a phase output signal of 45° with little amplitude attenuation may be provided.

As shown in Table 1, for A-CODE “0000” in the first quadrant, the auxiliary DAC controller 34 controls the auxiliary DAC circuit 140 not to generate an auxiliary output signal. The auxiliary DAC controller 34 may control the auxiliary DAC circuit 140 so that the auxiliary output signal is maximum at 8/64 steps corresponding to a phase of 45 degrees and the auxiliary output signal is minimum at 0/64 steps. The auxiliary DAC controller 34 may control the auxiliary DAC circuit 140 so that each of the I and Q signals of the auxiliary output signal changes in units of “0.4” at each step.

Table 2 shows the M-CODE and the corresponding A-CODE, which indicate phase interpolation using two orthogonal phase signals f180 and f090 from among the plurality of phase signals f000, f090, f180, and f270. The phase output signal generated using the two phase signals f180 and f090 according to M-CODE and A-CODE is located in the second quadrant's phase region.

TABLE 2

| | M-CODE | | | | | | | | | | |
|---|---|---|---|---|---|---|---|---|---|---|---|
| STEP | MSB | LSB | | Main DAC code | | | | Auxiliary DAC code | | | |
| INDEX | <1:0> | <3:0> | A-CODE | 0° | 90° | 180° | 270° | 0° | 90° | 180° | 270° |
| 16 | 01 | 0000 | 0000 | 0 | 16 | 0 | 0 | 0 | 0 | 0 | 0 |
| 17 | 01 | 0001 | 0001 | 0 | 15 | 1 | 0 | 0 | 1 | 1 | 0 |
| 18 | 01 | 0010 | 0010 | 0 | 14 | 2 | 0 | 0 | 2 | 2 | 0 |
| 19 | 01 | 0011 | 0011 | 0 | 13 | 3 | 0 | 0 | 3 | 3 | 0 |
| 20 | 01 | 0100 | 0100 | 0 | 12 | 4 | 0 | 0 | 4 | 4 | 0 |
| 21 | 01 | 0101 | 0101 | 0 | 11 | 5 | 0 | 0 | 5 | 5 | 0 |
| 22 | 01 | 0110 | 0110 | 0 | 10 | 6 | 0 | 0 | 6 | 6 | 0 |
| 23 | 01 | 0111 | 0111 | 0 | 9 | 7 | 0 | 0 | 7 | 7 | 0 |
| 24 | 01 | 1000 | 1000 | 0 | 8 | 8 | 0 | 0 | 8 | 8 | 0 |
| 25 | 01 | 1001 | 0111 | 0 | 7 | 9 | 0 | 0 | 7 | 7 | 0 |
| 26 | 01 | 1010 | 0110 | 0 | 6 | 10 | 0 | 0 | 6 | 6 | 0 |
| 27 | 01 | 1011 | 0101 | 0 | 5 | 11 | 0 | 0 | 5 | 5 | 0 |
| 28 | 01 | 1100 | 0100 | 0 | 4 | 12 | 0 | 0 | 4 | 4 | 0 |
| 29 | 01 | 1101 | 0011 | 0 | 3 | 13 | 0 | 0 | 3 | 3 | 0 |
| 30 | 01 | 1110 | 0010 | 0 | 2 | 14 | 0 | 0 | 2 | 2 | 0 |
| 31 | 01 | 1111 | 0001 | 0 | 1 | 15 | 0 | 0 | 1 | 1 | 0 |

As can be seen in Table 2, MSB<1:0> “01” indicates the second quadrant, and 16 codes from 16 to 31 out of 64 codes may indicate phase interpolation in the second quadrant. LSB<3:0> “0000” in the second quadrant may indicate the maximum weight of the Q signal and the minimum weight of the I signal. As the value of LSB<3:0> increases, the weight of the I signal may increase and the weight of the Q signal may decrease. LSB<3:0> “1111” in the second quadrant may indicate the minimum weight of the Q signal and the maximum weight of the I signal. In the second quadrant, according to LSB<3:0> “0000”, the main DAC controller 33 may control the main DAC circuit 130 to provide 16 90-degree phase currents. In the second quadrant, according to LSB<3:0> “0001”, the main DAC controller 33 may control the main DAC circuit 130 to provide 15 phase currents for the 90 degree phase and 1 phase current for the 180 degree phase. In the second quadrant, according to LSB<3:0> “1111”, the main DAC controller 33 controls the main DAC circuit 130 to provide 1 phase current for the 90 degree phase and 15 phase currents for the 180 degree phase.

When MSB<1:0> is “01,” the auxiliary DAC controller 34 may select the two orthogonal phase signals f180 and f090. The auxiliary DAC controller 34 may determine the A-CODE according to the phase control code LSB<3:0>. In the range “0000” to “1000” of the phase control code LSB<3:0>, the auxiliary DAC controller 34 may determine the A-CODE to be larger since the phase control code LSB<3:0> is larger according to the mapping table 35 implemented as shown in Table 2. Then, since the phase control code LSB<3:0> is larger, the weight of the I signal and the weight of the Q signal constituting the auxiliary output signal are large. In the range “1001” to “1111” of the phase control code LSB<3:0>, the auxiliary DAC controller 34 may determine the A-CODE to be small since the phase control code LSB <3:0> is larger according to the mapping table 35 implemented as shown in Table 2. Then, since the phase control code LSB<3:0> increases, the weight of the I signal and the weight of the Q signal constituting the auxiliary output signal are small.

In the second quadrant between the 90 degree phase and the 180 degree phase indicated by the upper 2 bits MSB<0:1> of the M-CODE, the auxiliary DAC controller 34 may determine the auxiliary code so that the weight of the I signal and the weight of the Q signal constituting the auxiliary output signal have the largest value when the M-CODE includes LSB<3:0> “1000” indicating the midpoint between 90 degrees and 180 degrees, i.e. 135 degrees.

The auxiliary DAC controller 34 may determine the auxiliary code so that the weight of the I signal and the weight of the Q signal of the auxiliary output signal have small values as the phase indicated by the M-CODE moves away from 135 degrees.

Table 3 shows the M-CODE indicating phase interpolation using two orthogonal phase signals f180 and f270 among the plurality of phase signals f000, f090, f180, and f270 and the corresponding A-CODE. The phase output signal generated using the two phase signals f180 and f270 according to the M-CODE and A-CODE is located in the third quadrant's phase region.

TABLE 3

| | M-CODE | | | | | | | | | | |
|---|---|---|---|---|---|---|---|---|---|---|---|
| STEP | MSB | LSB | | Main DAC code | | | | Auxiliary DAC code | | | |
| INDEX | <1:0> | <3:0> | A-CODE | 0° | 90° | 180° | 270° | 0° | 90° | 180° | 270° |
| 32 | 10 | 0000 | 0000 | 0 | 0 | 16 | 0 | 0 | 0 | 0 | 0 |
| 33 | 10 | 0001 | 0001 | 0 | 0 | 15 | 1 | 0 | 0 | 1 | 1 |
| 34 | 10 | 0010 | 0010 | 0 | 0 | 14 | 2 | 0 | 0 | 2 | 2 |
| 35 | 10 | 0011 | 0011 | 0 | 0 | 13 | 3 | 0 | 0 | 3 | 3 |
| 36 | 10 | 0100 | 0100 | 0 | 0 | 12 | 4 | 0 | 0 | 4 | 4 |
| 37 | 10 | 0101 | 0101 | 0 | 0 | 11 | 5 | 0 | 0 | 5 | 5 |
| 38 | 10 | 0110 | 0110 | 0 | 0 | 10 | 6 | 0 | 0 | 6 | 6 |
| 39 | 10 | 0111 | 0111 | 0 | 0 | 9 | 7 | 0 | 0 | 7 | 7 |
| 40 | 10 | 1000 | 1000 | 0 | 0 | 8 | 8 | 0 | 0 | 8 | 8 |
| 41 | 10 | 1001 | 0111 | 0 | 0 | 7 | 9 | 0 | 0 | 7 | 7 |
| 42 | 10 | 1010 | 0110 | 0 | 0 | 6 | 10 | 0 | 0 | 6 | 6 |
| 43 | 10 | 1011 | 0101 | 0 | 0 | 5 | 11 | 0 | 0 | 5 | 5 |
| 44 | 10 | 1100 | 0100 | 0 | 0 | 4 | 12 | 0 | 0 | 4 | 4 |
| 45 | 10 | 1101 | 0011 | 0 | 0 | 3 | 13 | 0 | 0 | 3 | 3 |
| 46 | 10 | 1110 | 0010 | 0 | 0 | 2 | 14 | 0 | 0 | 2 | 2 |
| 47 | 10 | 1111 | 0001 | 0 | 0 | 1 | 15 | 0 | 0 | 1 | 1 |

As can be seen in Table 3, MSB<1:0> “01” indicates the third quadrant, and among 64 codes, 16 codes from 32 to 47 may indicate phase interpolation in the third quadrant. LSB<3:0> “0000” in the third quadrant may indicate the maximum weight of the I signal and the minimum weight of the 0 signal. Since the value of LSB<3:0> is larger, the weight of the I signal may decrease and the weight of the 0 signal may increase. LSB<3:0> “1111” in the third quadrant may indicate the minimum weight of the I signal and the maximum weight of the 0 signal. In the third quadrant, according to LSB<3:0> “0000”, the main DAC controller 33 may control the main DAC circuit 130 to provide 16 180-degree phase currents. In the third quadrant, according to LSB<3:0> “0001”, the main DAC controller 33 may control the main DAC circuit 130 to provide 15 phase currents for the 180-degree phase and 1 phase current for 270-degree phase. In the third quadrant, according to LSB<3:0> “1111”, the main DAC controller 33 may control the main DAC circuit 130 to provide 1 phase current for the 180-degree phase and 15 phase currents for the 270-degree phase.

When MSB<1:0> is “10,” the auxiliary DAC controller 34 may select the two orthogonal phase signals f180 and f270. The auxiliary DAC controller 34 may determine the A-CODE according to the phase control code LSB<3:0>. In the range “0000” to “1000” of the phase control code LSB<3:0>, the auxiliary DAC controller 34 may determine the A-CODE to be large since the phase control code LSB<3:0> is larger according to the mapping table 35 implemented as shown in Table 3. Then, since the phase control code LSB<3:0> is larger, the weight of the I signal and the weight of the Q signal constituting the auxiliary output signal are large. In the range “1001” to “1111” of the phase control code LSB<3:0>, the auxiliary DAC controller 34 may determine the A-CODE to be small since the phase control code LSB<3:0> is larger according to the mapping table 35 implemented as shown in Table 3. Then, since the phase control code LSB<3:0> increases, the weight of the I signal and the weight of the Q signal constituting the auxiliary output signal are small.

In the third quadrant between the 180-degree phase and the 270-degree phase indicated by the upper 2 bits MSB<1:0> of the M-CODE, the auxiliary DAC controller 34 may determine that the weight of the I signal and the weight of the Q signal constituting the auxiliary output signal have the largest values when the M-CODE includes LSB<3:0> “1000” indicating the midpoint between 180 degrees and 270 degrees, i.e., 225 degrees. The auxiliary DAC controller 34 may determine the auxiliary code so that the weight of the I signal and the weight of the Q signal of the auxiliary output signal have smaller values as the phase indicated by the M-CODE moves away from 45 degrees.

Table 4 shows the M-CODE indicating phase interpolation using two orthogonal phase signals f000 and f270 from among the plurality of phase signals f000, f090, f1 80, and f270 and the corresponding A-CODE. The phase output signal generated using the two phase signals f000 and f270 according to the M-CODE and A-CODE is located in the fourth quadrant's phase region.

TABLE 4

| | M-CODE | | | | | | | | | | |
|---|---|---|---|---|---|---|---|---|---|---|---|
| STEP | MSB | LSB | | Main DAC code | | | | Auxiliary DAC code | | | |
| INDEX | <1:0> | <3:0> | A-CODE | 0° | 90° | 180° | 270° | 0° | 90° | 180° | 270° |
| 48 | 11 | 0000 | 0000 | 0 | 0 | 0 | 16 | 0 | 0 | 0 | 0 |
| 49 | 11 | 0001 | 0001 | 1 | 0 | 0 | 15 | 1 | 0 | 0 | 1 |
| 50 | 11 | 0010 | 0010 | 2 | 0 | 0 | 14 | 2 | 0 | 0 | 2 |
| 51 | 11 | 0011 | 0011 | 3 | 0 | 0 | 13 | 3 | 0 | 0 | 3 |
| 52 | 11 | 0100 | 0100 | 4 | 0 | 0 | 12 | 4 | 0 | 0 | 4 |
| 53 | 11 | 0101 | 0101 | 5 | 0 | 0 | 11 | 5 | 0 | 0 | 5 |
| 54 | 11 | 0110 | 0110 | 6 | 0 | 0 | 10 | 6 | 0 | 0 | 6 |
| 55 | 11 | 0111 | 0111 | 7 | 0 | 0 | 9 | 7 | 0 | 0 | 7 |
| 56 | 11 | 1000 | 1000 | 8 | 0 | 0 | 8 | 8 | 0 | 0 | 8 |
| 57 | 11 | 1001 | 0111 | 9 | 0 | 0 | 7 | 7 | 0 | 0 | 7 |
| 58 | 11 | 1010 | 0110 | 10 | 0 | 0 | 6 | 6 | 0 | 0 | 6 |
| 59 | 11 | 1011 | 0101 | 11 | 0 | 0 | 5 | 5 | 0 | 0 | 5 |
| 60 | 11 | 1100 | 0100 | 12 | 0 | 0 | 4 | 4 | 0 | 0 | 4 |
| 61 | 11 | 1101 | 0011 | 13 | 0 | 0 | 3 | 3 | 0 | 0 | 3 |
| 62 | 11 | 1110 | 0010 | 14 | 0 | 0 | 2 | 2 | 0 | 0 | 2 |
| 63 | 11 | 1111 | 0001 | 15 | 0 | 0 | 1 | 1 | 0 | 0 | 1 |

As can be seen in Table 4, MSB<1:0> “11” indicates the fourth quadrant, and among the 64 codes, 16 codes from 48 to 63 may indicate phase interpolation in the fourth quadrant. LSB<3:0> “0000” in the fourth quadrant may indicate the maximum weight of the Q signal and the minimum weight of the I signal. Since the value of LSB<3:0> is larger, the weight of the I signal may increase and the weight of the Q signal may decrease. LSB<3:0> “1111” in the fourth quadrant may indicate the minimum weight of the Q signal and the maximum weight of the I signal. In the fourth quadrant, according to LSB<3:0> “0000”, the main DAC controller 33 may control the main DAC circuit 130 to provide 16 270-degree phase currents. In the fourth quadrant, according to LSB<3:0> “0001”, the main DAC controller 33 may control the main DAC circuit 130 to provide 15 phase currents for the 270 degree phase and 1 phase current for the 0 degree phase. In the fourth quadrant, according to LSB<3:0> “1111”, the main DAC controller 33 may control the main DAC circuit 130 to provide 15 phase currents for the 0 degree phase and 1 phase current for the 270 degree phase.

When MSB<1:0> is “11,” the auxiliary DAC controller 34 may select the two orthogonal phase signals f000 and f270. The auxiliary DAC controller 34 may determine the A-CODE according to the phase control code LSB<3:0>. In the range “0000” to “1000” of the phase control code LSB<3:0>, the auxiliary DAC controller 34 may determine the A-CODE to be larger since the phase control code LSB<3:0> is larger according to the mapping table 35 implemented as shown in Table 4. Then, since the phase control code LSB<3:0> is larger, the weight of the I signal and the weight of the Q signal constituting the auxiliary output signal become large. In the range “1001” to “1111” of the phase control code LSB<3:0>, the auxiliary DAC controller 34 may determine the A-CODE to be small since the phase control code LSB<3:0> is larger according to the mapping table 35 implemented as shown in Table 4. Then, since the phase control code LSB<3:0> is larger, the weight of the I signal and the weight of the Q signal constituting the auxiliary output signal are small.

In the second quadrant between the 270 degree phase and 0 degrees phase indicated by the upper 2 bits MSB<0:1> of the M-CODE, the auxiliary DAC controller 34 may determine the auxiliary code so that the weight of the I signal and the weight of the Q signal constituting the auxiliary output signal have the largest value when the M-CODE includes LSB<3:0> “1000” indicating the middle between 270 degrees and 0 degrees, i.e., 315 degrees. The auxiliary DAC controller 34 may determine the auxiliary code so that the weight of the I signal and the weight of the Q signal of the auxiliary output signal have smaller values as the phase indicated by the M-CODE moves away from 315 degrees.

In this manner, when the auxiliary DAC circuit 140 provides phase interpolation according to the A-CODE according to the M-CODE, as shown in FIG. 6, the phase constellation 600 of the phase output current may form an octagon.

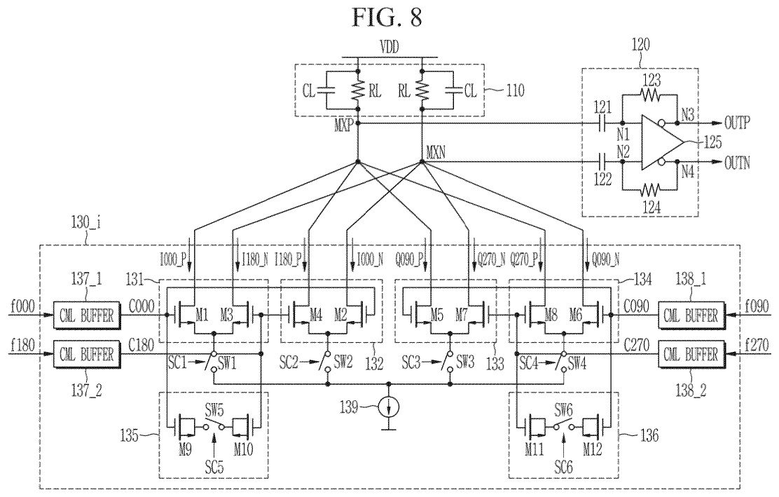

FIG. 8 is a circuit diagram showing one of the main DAC circuits according to an embodiment of the disclosure.

In FIG. 8, the main circuit (130_i, i is one of the natural numbers from 1 to 16), which is one of the plurality of main DAC circuits 130, includes four transconductance stages 131, 132, 133 and 134, four switches SW1, SW2, SW3 and SW4, a bias current source 139, two dummy stages 135 and 136, and four CML buffers 137_1, 137_2, 138_1, and 138_2.

The four CML buffers 137_1, 1372, 138_1, and 138_2 respectively buffer four phase signals f000, f180, f090 and f270 having the CMOS level to the CML level to generate four phase signals C000, C180, C090 and C270. Hereinafter, each of the four phase signals C000, C090, C180, and C270 having the CML level is referred to as a phase input signal.

Each of the four transconductance stages 131 to 134 may adjust the phase currents for each of the two nodes MXP and MXN according to two corresponding phase input signals, which are inverted relative to each other. Each of the four transconductance stages 131 to 134 may include two differential input transistors connected to each of the two nodes MXP and MXN.

For example, the transconductance stage 131 may adjust each of the phase currents respectively flowing from the load circuit 110 to the node MXP and node MXN according to the phase input signal C000 and the phase input signal C180. The transconductance stage 131 may include a transistor M1 connected to the node MXP and a transistor M3 connected to the node MXN. The transistor M1 may include a drain connected to the node MXP, a gate to which the phase input signal C000 is input, and a source connected to one end of the switch SW1. The transistor M3 may include a drain connected to the node MXN, a gate to which the phase input signal C180 is input, and a source connected to one end of the switch SW1. A phase current I000_P according to the product of the phase input signal C000 and the effective transconductance of the transistor M1 may flow to the transistor M1, and a phase current I180_N according to the product of the phase input signal C180 and the effective transconductance of the transistor M3 may flow to the transistor M3.

The transconductance stage 132 may adjust the phase currents flowing from the load circuit 110 to the node MXP and node MXN according to the phase input signal C180 and the phase input signal C000, respectively. The transconductance stage 132 may include a transistor M4 connected to the node MXP and a transistor M2 connected to the node MXN. The transistor M4 may include a drain connected to the node MXP, a gate to which the phase input signal C180 is input, and a source connected to one end of the switch SW2. The transistor M2 may include a drain connected to the node MXN, a gate to which the phase input signal C000 is input, and a source connected to one end of the switch SW2. A phase current I180_P according to the product of the phase input signal C180 and the effective transconductance of the transistor M4 may flow to the transistor M4, and a phase current I000_N corresponding to the phase input signal C000 and the effective transconductance of the transistor M2 may flow to the transistor M2.

The transconductance stage 133 may adjust each of the phase currents flowing from the load circuit 110 to each of the node MXP and node MXN according to the phase input signal C090 and the phase input signal C270. The transconductance stage 133 may include a transistor M5 connected to the node MXP and a transistor M7 connected to the node MXN. The transistor M5 may include a drain connected to the node MXP, a gate to which the phase input signal C090 is input, and a source connected to one end of the switch SW3. The transistor M7 may include a drain connected to the node MXN, a gate to which the phase input signal C270 is input, and a source connected to one end of the switch SW3. A phase current Q090_P according to the product of the phase input signal C090 and the effective transconductance of the transistor M5 flows to the transistor M5, and a phase current Q270_N according to the product of the phase input signal C270 and the effective transconductance of the transistor M7 may flow to the transistor M7.

The transconductance stage 134 may adjust each of the phase currents flowing from the load circuit 110 to each of the nodes MXP and MXN according to the phase input signal C270 and the phase input signal C090. The transconductance stage 134 may include a transistor M8 connected to the node MXP and a transistor M6 connected to the node MXN. The transistor M8 may include a drain connected to the node MXP, a gate to which the phase input signal C270 is input, and a source connected to one end of the switch SW4. The transistor M6 may include a drain connected to the node MXN, a gate to which the phase input signal C090 is input, and a source connected to one end of the switch SW4. A phase current Q270_P according to the product of the phase input signal C270 and the effective transconductance of the transistor M8 may flow to the transistor M8, and a phase current Q090_N according to the product of the phase input signal C090 and the effective transconductance of the transistor M6 may flow to the transistor M6.

The other end of the switch SW1 is connected to the bias current source 139, and the other end of the switch SW2 is connected to the bias current source 139. The other end of the switch SW3 is connected to the bias current source 139, and the other end of the switch SW4 is connected to the bias current source 139. The switch SW1 may perform a switching operation according to a switching signal SC1, the switch SW2 may perform a switching operation according to a switching signal SC2, the switch SW3 may perform a switching operation according to a switching signal SC3, and the switch SW4 may perform a switching operation according to a switching signal SC4.

For example, the main DAC controller 33 may provide an ON-level switching signal SC1 and OFF-level switching signal SC2 to SC4 to a plurality of switches SW1 to SW4 according to the M-CODE. Then, the switch SW1 may be turned on and the plurality of switches SW2 to SW4 may be turned off. The bias current source 139 may be connected to the transconductance stage 131, and the phase current I000_P according to the product of the phase input signal C000 and the effective transconductance of the transistor M1 may flow to the transistor M1, and the phase current I180_N according to the product of the phase input signal C180 and the effective transconductance of the transistor M3 may flow to the transistor M3. The sum of the phase current I000_P and the phase current I180_N may be equal to a current that the bias current source 139 sinks. When the phase input signal C000 is at a high level with respect to the phase input signal C180, the phase current I000_P may be larger than the phase current I180_N. Conversely, the phase current I180_N may be larger than the phase current I000_P.

In the same manner as described above, when each of the switching signals SC2 to SC4 is at the ON level, corresponding phase current signals may flow.

The dummy stage 135 may include two transistors M9 and M10 and a switch SW5. A gate of transistor M9 is connected to the gate of transistor M1 and the gate of transistor M2, and source and drain of the transistor M9 are connected to each other. A gate of transistor M10 is connected to the gate of transistor M3 and the gate of transistor M4, and source and drain of the transistor M10 are connected to each other. A switch SW5 is connected between the source/drain of the transistor M9 and the source/drain of the transistor M10. The switch SW5 may perform a switching operation according to a switching signal SC5.

The dummy stage 136 may include two transistors M11 and M12 and a switch SW6. The gate of transistor M11 is connected to the gate of transistor M7 and the gate of transistor M8, and the source and drain of transistor M11 are connected to each other. The gate of transistor M12 is connected to the gate of transistor M5 and the gate of transistor M6, and the source and drain of transistor M12 are connected to each other. A switch SW6 is connected between the source/drain of the transistor M11 and the source/drain of the transistor M12. The switch SW6 may perform a switching operation according to a switching signal SC6.

An operating region of each of the four pairs of transistors M1/M2, M3/M4, M5/M6, and M7/M8 varies depending on each of the four phase input signals C000, C090, C180, and C270. Accordingly, parasitic capacitance between the gate and source of each of the four pairs of transistors M1/M2, M3/M4, M5/M6, and M7/M8 may change. To improve the non-linearity resulting from this changed parasitic capacitance, the dummy transistors M9 to M12 may be provided.

For example, when the main DAC circuit 130_i provides a 0-degree phase current or a 180-degree phase current, the main DAC controller 33 generates an ON-level switching signal SC6 and an OFF-level switching signal SC5. Then, the switch SW6 may be turned on to enable capacitance compensation for the transistors M5 to M8 using the transistors M11 and M12. When the main DAC circuit 130_i provides a 0-degree phase current or a 180-degree phase current, the switches SW3 and SW4 are in an OFF state, causing the transistors M5 to M8 to be in the OFF state. Gate-source parasitic capacitance (hereinafter referred to as Cgs) of a transistor operating in a saturation region is larger by 2/3WLCox compared to Cgs of a transistor in an OFF state (W: transistor channel width, L: transistor channel length, Cox: oxide capacitance of transistor). To compensate for the difference, the transistors M9 to M12, with a channel width (0.5 W) half that of the transistors M1 to M8, may be used. When the switch SW6 is turned on, each of the transistors M11 and M12 operates in a linear region (triode) to provide additional gate-source parasitic capacitance “1/2(0.5 W)LCox+(0.5 W)Cov” and gate-drain parasitic capacitance “1/2(0.5 W)LCox” to the gates of the turned-off transistors M5 to M8 (where Cov: overlap capacitance). This compensates for variations due to differences between the input loads of the plurality of transistors M1 to M8.

In contrast, when the main DAC (130_i) circuit provides a 90-degree phase current or a 270-degree phase current, the main DAC controller 33 may generate an ON-level switching signal SC5 and an OFF-level switching signal SC6. The switch SW5 may be turned on so that capacitance compensation for the transistors M1 to M4 may be provided by the transistors M9 and M10.

The main DAC controller 33 may generate each of a plurality of main control signals MSW_1 to MSW_16 according to the M-CODE. Each of the plurality of main control signals MSW_1 to MSW_16 may include a plurality of switching signals SC1 to SC6. The main DAC controller 33 may generate each of a plurality of main control signals MSW_1 to MSW_16 according to the weight for each of the phase of the I signal and the phase of the Q signal based on the M-CODE. For example, when the M-CODE is “100111”, the main DAC controller 33 may generate each of nine main control signals, among the plurality of main control signals MSW_1 to MSW_16, to include ON-level switching signals SC2 and SC6 and OFF-level switching signals SC1, SC3, SC4, and SC5 and generate each of seven main control signals, among the plurality of main control signals MSW_1 to MSW_16, to include ON-level switching signals SC4 and SC5 and OFF-level switching signals SC1, SC2, SC3, and SC6 according to the weight 9 for the I signal having the 180-degree phase and the weight 7 for the Q signal having the phase of 270 degrees in Table 3.

A plurality of DACs constituting the auxiliary DAC circuit 140 may also be implemented in the same manner as the DACs constituting the main DAC circuit 130. However, this is just an example, and the auxiliary DAC circuit 140 may be implemented in a different manner from the circuit shown in FIG. 8.

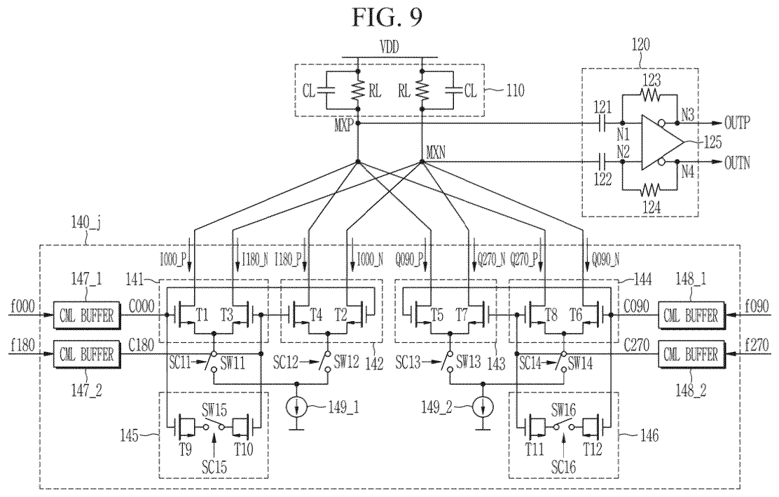

FIG. 9 is a circuit diagram showing one of auxiliary DAC circuits according to an embodiment of the disclosure.

The same description of FIG. 9 as the description given above with reference to FIG. 8 is omitted. In FIG. 9, the reference symbols for each of the phase currents flowing in the auxiliary DAC are the same as the reference symbols for each of the in-phase phase currents flowing in the main DAC.

In FIG. 9, the auxiliary circuit 140_j (j is one of the natural numbers from 1 to 8), which is one of the plurality of auxiliary DAC circuits 140, may include four transconductance stages 141, 142, 143 and 144, four switches SW11, SW12, SW13 and SW14, two bias current sources 149_1 and 1492, two dummy stages 145 and 146, and four CML buffers 147_1, 1472, 148_1, and 148_2.

The four CML buffers 147_1, 1472, 148_1, and 148_2 may buffer the four phase signals f000, f090, f180, and f270 having the CMOS level to the CML level to generate four phase input signals C000, C090, C180, and C270, respectively.

Each of the four transconductance stages 141 to 144 may adjust phase currents for each of the two nodes MXP and MXN according to two corresponding phase input signals that are inverted relative to each other. Each of the four transconductance stages 141 to 144 may include each of two differential input transistors respectively connected to the two nodes MXP and MXN.

For example, the transconductance stage 141 may adjust each of the phase currents flowing from the load circuit 110 to the node MXP and node MXN according to each of the phase input signal C000 and the phase input signal C180. The transconductance stage 131 may include a transistor T1 connected to the node MXP and a transistor T3 connected to the node MXN. The transistor T1 may include a drain connected to the node MXP, a gate to which the phase input signal C000 is input, and a source connected to one end of the switch SW11. The transistor T3 may include a drain connected to the node MXN, a gate to which the phase input signal C180 is input, and a source connected to one end of the switch SW11. A phase current I000_P according to the product of the phase input signal C000 and the effective transconductance of the transistor T1 may flow to the transistor T1, and a phase current I180_N according to the product of the phase input signal C180 and the effective transconductance of the transistor T3 may flow to the transistor T3.

The transconductance stage 142 may adjust the phase currents flowing from the load circuit 110 to the node MXP and node MXN according to the phase input signal C180 and the phase input signal C000, respectively. The transconductance stage 142 may include a transistor T4 connected to the node MXP and a transistor T2 connected to the node MXN. The transistor T4 may include a drain connected to the node MXP, a gate to which the phase input signal C180 is input, and a source connected to one end of the switch SW12. The transistor T2 may include a drain connected to the node MXN, a gate to which the phase input signal C000 is input, and a source connected to one end of the switch SW12. A phase current I180_P according to the product of the phase input signal C180 and the effective transconductance of the transistor T4 may flow to the transistor T4, and a phase current I000_N according to the product of the phase input signal C000 and the effective transconductance of the transistor T2 may flow to the transistor T2.

The transconductance stage 143 may adjust each of the phase currents flowing from the load circuit 110 to each of the node MXP and node MXN according to the phase input signal C090 and the phase input signal C270. The transconductance stage 143 may include a transistor T5 connected to the node MXP and a transistor T7 connected to the node MXN. The transistor T5 may include a drain connected to the node MXP, a gate to which the phase input signal C090 is input, and a source connected to one end of the switch SW13. The transistor T7 may include a drain connected to the node MXN, a gate to which the phase input signal C270 is input, and a source connected to one end of the switch SW13. A phase current Q090_P according to the product of the phase input signal C090 and the effective transconductance of the transistor T5 may flow to the transistor T5, and a phase current Q270_N according to the product of the phase input signal C270 and the effective transconductance of the transistor T7 may flow to the transistor T7.

The transconductance stage 144 may adjust each of the phase currents flowing from the load circuit 110 to each of the nodes MXP and MXN according to the phase input signal C270 and the phase input signal C090. The transconductance stage 144 may include a transistor T8 connected to the node MXP and a transistor T6 connected to the node MXN. The transistor T8 may include a drain connected to the node MXP, a gate to which the phase input signal C270 is input, and a source connected to one end of the switch SW14. The transistor T6 may include a drain connected to the node MXN, a gate to which the phase input signal C090 is input, and a source connected to one end of the switch SW14. A phase current Q270_P according to the product of the phase input signal C270 and the effective transconductance of the transistor T8 may flow to the transistor T8, and a phase current Q090_N according to the product of the phase input signal C090 and the effective transconductance of the transistor T6 may flow to the transistor T6.

The other end of the switch SW11 is connected to the bias current source 149_1 and the other end of the switch SW12 is connected to the bias current source 149_1. The other end of the switch SW13 is connected to the bias current source 1492, and the other end of the switch SW14 is connected to the bias current source 149_2. The current of each of the two bias current sources 149_1 and 149_2 may be determined based on the degree of current compensation for the main output signal. For example, according to the current level of the compensation output signal as described above with reference to FIG. 7, the current of each of the two bias current sources 149_1 and 149_2 may be set to 0.4 time the current provided by the current source 139 of the main DAC.

The switch SW11 may perform a switching operation according to a switching signal SC11, the switch SW12 may perform a switching operation according to a switching signal SC12, the switch SW13 may perform a switching operation according to a switching signal SC13, and the switch SW14 may perform a switching operation according to a switching signal SC14. For example, when two orthogonal phase inputs determined by M-CODE are 0 degrees and 90 degrees, the auxiliary DAC controller 34 may provide ON-level switching signals SC11 and SC13 and OFF-level switching signals SC12 and SC14 to a plurality of switches SW11 to SW14 according to the A-CODE. Then, the switches SW11 and SW13 may be turned on, and the switches SW12 and SW14 may be turned off. The bias current source 149_1 is connected to the transconductance stage 141, the bias current source 149_2 is connected to the transconductance stage 143, current of the bias current source 149_1 flows in the transconductance stage 141, and current of the bias current source 149_2 flows in the transconductance stage 143.

The phase current I000_P according to the product of the phase input signal C000 and the effective transconductance of the transistor T1 may flow to the transistor T1, and the phase current I180_N according to the product of the phase input signal C180 and the effective transconductance of the transistor T3 may flow to the transistor T3. When the phase input signal C000 is at a high level with respect to the phase input signal C180, the phase current I000_P may be larger than the phase current I180_N.

Conversely, the phase current I180_N may be larger than the phase current I000_P.

The phase current Q090_P, determined by the product of the phase input signal C090 and the effective transconductance of the transistor T5, flow through the transistor T5. Similarly, the phase current Q270_N determined by the product of the phase input signal C270 and the effective transconductance of the transistor T7, flows through the transistor T7. When the phase input signal C090 is at a high level with respect to the phase input signal C270, the phase current Q090_P may be larger than the phase current Q270_N. Conversely, the phase current Q270_N may be larger than the phase current Q090_P.

The phase current I000_P provided by the auxiliary DAC(140_j) may overlap the phase current I000_P provided by the main DAC circuit 130, and the phase current I180_N provided by the auxiliary DAC(140_j) may overlap the phase current I180_N provided by the main DAC circuit 130. The phase current Q090_P provided by the auxiliary DAC(140_j) may overlap the phase current Q090_P provided by the main DAC circuit 130, and the phase current Q270_N provided by the auxiliary DAC(140_j) may overlap the phase current Q270_N provided by the main DAC circuit 130.

When the two orthogonal phase inputs determined by the M-CODE are 0 degrees and 270 degrees, the auxiliary DAC controller 34 may provide the ON-level switching signals SC11 and SC14 and the OFF-level switching signals SC12 and SC13 to the plurality of switches SW11 to SW14 according to the A-CODE. Alternatively, when the orthogonal two phase inputs determined by the M-CODE are 180 degrees and 90 degrees, the auxiliary DAC controller 34 may provide the ON-level switching signals SC12 and SC13 and the OFF-level switching signals SC11 and SC14 to the plurality of switches SW11 to SW14 according to the A-CODE. Alternatively, when the two orthogonal phase inputs determined by the M-CODE are 180 degrees and 270 degrees, the auxiliary DAC controller 34 may provide the ON-level switching signals SC12 and SC14 and the OFF-level switching signals SC11 and SC13 to the plurality of switches SW11 to SW14 according to the A-CODE. When two switching signals SC11/SC14, SC12/SC13, and SC12/S14 corresponding to two orthogonal phases, among the plurality of switching signals SC11 to SC14, are at the ON level, the corresponding phase current signals may flow to the auxiliary DAC(140_j).

The dummy stage 145 may include two transistors T9 and T10 and a switch SW15. A gate of the transistor T9 is connected to the gate of the transistor T1 and the gate of the transistor T2, and source and drain of the transistor T9 are connected to each other. A gate of the transistor T10 is connected to the gate of the transistor T3 and the gate of the transistor T4, and source and drain of the transistor T10 are connected to each other. The switch SW15 is connected between the source/drain of the transistor T9 and the source/drain of the transistor T10. The switch SW15 may perform a switching operation according to a switching signal SC15.

The dummy stage 146 may include two transistors T11 and T12 and a switch SW16. A gate of the transistor T11 is connected to the gate of the transistor T7 and the gate of the transistor T8, and source and drain of the transistor T11 are connected to each other. A gate of the transistor T12 is connected to the gate of the transistor T5 and the gate of the transistor T6, and source and drain of the transistor T12 are connected to each other. The switch SW16 is connected between the source/drain of the transistor T11 and the source/drain of the transistor T12. The switch SW16 may perform a switching operation according to a switching signal SC16.

The auxiliary DAC controller 34 may generate each of a plurality of auxiliary control signals ASW_1 to ASW_8 according to the A-CODE. Each of the plurality of auxiliary control signals ASW_1 to ASW_8 may include a plurality of switching signals SC11 to SC16. The auxiliary DAC controller 34 may determine the phase of each of the two orthogonal phase signals (I signal and Q signal) according to the M-CODE, and generate each of the plurality of auxiliary control signals ASW_1 to ASW_8 based on the weight for each of the phase of the I signal and the phase of the Q signal according to the A-CODE corresponding to the M-CODE. For example, when the M-CODE is “100111”, the auxiliary DAC controller 34 may determine the phase of the I signal to be 180 degrees and the phase of the Q signal to be 270 degrees according to MSB<1:0>“10”. The auxiliary DAC controller 34 may generate each of seven auxiliary control signals, among the plurality of auxiliary control signals ASW_1 to ASW_8, to include the ON-level switching signals SC12 and SC14 and the OFF-level switching signals SC11 and SC13 according to a weight 7 for the I signal having the phase of 180 degrees and a weight 7 for the Q signal having the phase of 270 degrees based on the A-CODE of Table 3. The auxiliary DAC controller 34 may generate the remaining auxiliary control signal, among the plurality of auxiliary control signals ASW_1 to ASW_8, to include the OFF-level switching signals SC11 to SC14.

In the description above, it is assumed that the number of auxiliary DAC circuits constituting the auxiliary DAC circuit is 8, unlike the number of DAC circuits constituting the main DAC circuit 130, but the disclosure is not limited thereto.

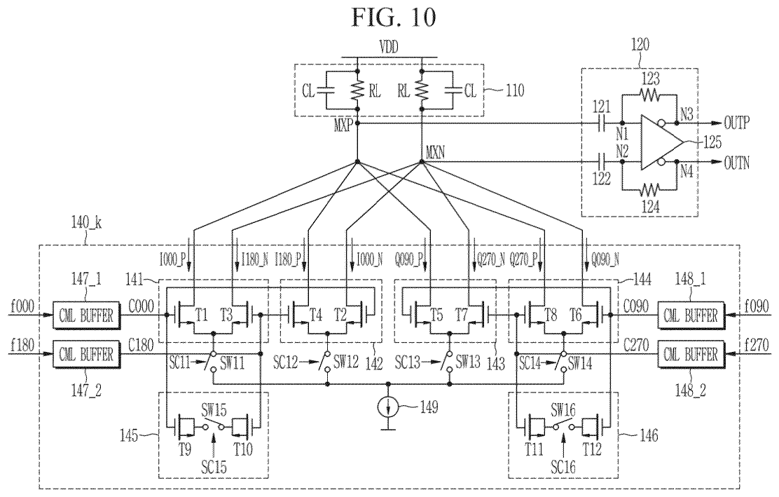

FIG. 10 is a circuit diagram showing one of auxiliary DAC circuits according to an embodiment of the disclosure.

In the auxiliary DAC shown in FIG. 10, the auxiliary DAC circuit 140 may include the same number of auxiliary DACs as the number of main DACs included in the main DAC circuit 130. In the auxiliary DAC shown in FIG. 9, each of two bias current sources is provided to each of the two transconductance stages, but the auxiliary DAC 140k shown in FIG. 10 may include just one bias current source 149. A description of the configuration of the auxiliary DAC 140k shown in FIG. 10, which is the same as the configuration of the auxiliary DAC 140j shown in FIG. 9, is omitted. k may be one of the natural numbers from 1 to 16.

The other end of each of the plurality of switches SW11 to SW14 is connected to the bias current source 149. Since the number of auxiliary DACs constituting the auxiliary DAC circuit 140 is 16, only one of the plurality of switches SW11 to SW14 of each auxiliary DAC is turned on.

When the two orthogonal phase inputs determined by the M-CODE are 0 degrees and 90 degrees, the auxiliary DAC controller 34 may provide an ON-level switching signal SC11 and OFF-level switching signals SC12 to SC14 to the number of auxiliary DACs corresponding to the A-CODE, and an ON-level switching signal SC13 and OFF-level switching signals SC11, SC12, and SC14 to the number of different auxiliary DACs according to the A-CODE. When the two orthogonal phase inputs determined by the M-CODE are 180 degrees and 90 degrees, the auxiliary DAC controller 34 may provide an ON-level switching signal SC12 and OFF-level switching signals SC11, SC13, and SC14 to the number of auxiliary DACs corresponding to the A-CODE, and an ON-level switching signal SC13 and OFF-level switching signals SC11, SC12, and SC14 to the number of different auxiliary DACs according to the A-CODE. When the two orthogonal phase inputs determined by the M-CODE are 180 degrees and 270 degrees, the auxiliary DAC controller 34 may provide an ON-level switching signal SC12 and OFF-level switching signals SC11, SC13, and SC14 to the number of auxiliary DACs corresponding to the A-CODE, and an ON-level switching signal SC14 and OFF-level switching signals SC11 to SC13 to the number of different auxiliary DACs according to the A-CODE. When the two orthogonal phase inputs determined by the M-CODE are 0 degrees and 270 degrees, the auxiliary DAC controller 34 may provide an ON-level switching signal SC11 and OFF-level switching signals SC12 to SC14 to the number of auxiliary DACs corresponding to the A-CODE, and an ON-level switching signal SC14 and OFF-level switching signals SC11 to SC13 to the number of different auxiliary DACs according to the A-CODE.

The auxiliary DAC controller 34 may generate each of 16 auxiliary control signals according to the A-CODE. Each of the 16 auxiliary control signals may include the plurality of switching signals SC11 to SC16. The auxiliary DAC controller 34 may determine the phase of the I signal and the phase of the Q signal according to the M-CODE and generate each of the 16 auxiliary control signals according to the weight for each of the phase of the I signal and the phase of the Q signal according to the A-CODE corresponding to the M-CODE. For example, when the M-CODE is “100111”, the auxiliary DAC controller 34 may determine the phase of the I signal to be 180 degrees and the phase of the Q signal to be 270 degrees according to MSB<1:0> “10”. The auxiliary DAC controller 34 may generate each of seven of the 16 auxiliary control signals to include the ON-level switching signal SC12 and the OFF-level switching signals SC11, SC13, and SC14 according to the weight of 7 for the I signal having the phase of 180 degrees based on the A-CODE in Table 3. The auxiliary DAC controller 34 may generate each of the other seven of the 16 auxiliary control signals to include the ON-level switching signal SC14 and the OFF-level switching signals SC11 to SC13 according to the weight of 7 for the I signal having the phase of 270 degrees based on the A-CODE in Table 3. The auxiliary DAC controller 34 may generate the remaining 2 auxiliary control signals among the 16 auxiliary control signals to include OFF-level switching signals SC11 to SC14.

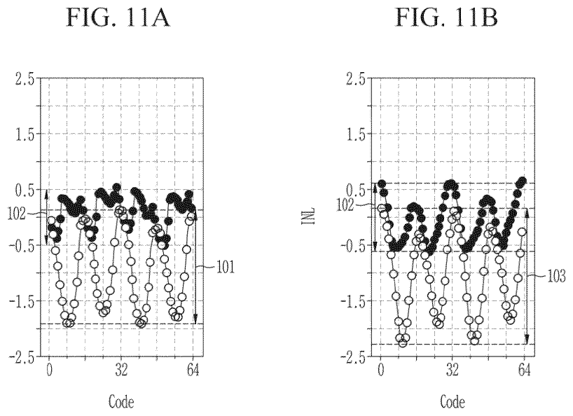

FIGS. 11A and 11B are graphs showing improved integral non-linearity with the addition of an auxiliary DAC circuit.

FIG. 11A shows the integral non-linearity (INL) of a phase output signal for each code when the frequency of the phase signal is 3.6 GHz, and FIG. 11B shows the integral non-linearity (INL) of a phase output signal for each code when the frequency of the phase signal is 1.4 GHz. In each graph, the horizontal axis represents the code indicating phase interpolation, and the vertical axis represents “LSB (Least Significant Bit)”. “LSB” is used as a unit to represent the integral non-linearity by normalizing it for each code. According to an embodiment including the auxiliary DAC circuit 140, the integral non-linearity of the phase output signal for each code is indicated by black dots, and the integral non-linearity when the auxiliary DAC circuit 140 is not present is indicated by small circles.

As shown in FIG. 11A, an integral non-linearity 102 improved by the auxiliary DAC circuit 140 is 1.06 LSB, which is smaller than an integral non-linearity 101 of 2.06 LSB without the auxiliary DAC circuit 140.

In addition, as shown in FIG. 11B, an integral non-linearity 104 improved by the auxiliary DAC circuit 140 is 1.26 LSB, which is smaller than an integral non-linearity 103 of 2.44 LSB without the auxiliary DAC circuit 140.

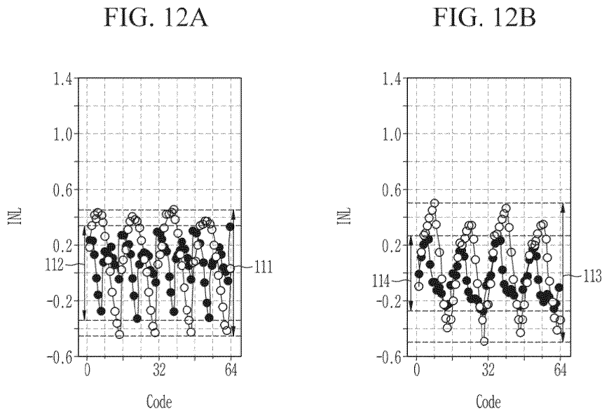

FIGS. 12A and 12B are graphs showing improved differential linearity with the addition of an auxiliary DAC circuit.

FIG. 12A shows the differential non-linearity (DNL) of a phase output signal for each code when the frequency of the phase signal is 3.6 GHz, and FIG. 12B shows the differential non-linearity (DNL) of a phase output signal for each code when the frequency of the phase signal is 1.4 GHz. In each graph, the horizontal axis represents the code indicating phase interpolation, and the vertical axis represents “LSB”. “LSB” is used as a unit to represent the differential non-linearity by normalizing it for each code. According to an embodiment including the auxiliary DAC circuit 140, the differential non-linearity of the phase output signal for each code is indicated by black dots, and the differential non-linearity when the auxiliary DAC circuit 140 is not present is indicated by small circles.

As shown in FIG. 12A, a differential non-linearity 112 improved by the auxiliary DAC circuit 140 is 0.66 LSB, which is smaller than a differential non-linearity 111 of 0.92 LSB in the absence of the auxiliary DAC circuit 140.

In addition, as shown in FIG. 12B, a differential non-linearity 114 improved by the auxiliary DAC circuit 140 is 0.54 LSB which is smaller than a differential non-linearity 113 of 1.01 LSB without the auxiliary DAC circuit 140.

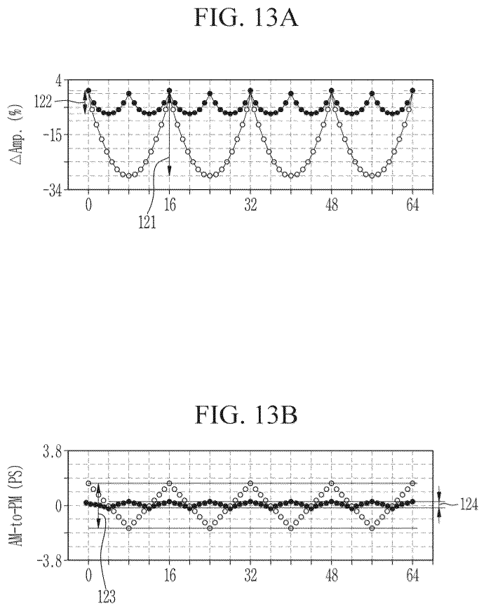

FIGS. 13A and 13B are graphs showing improved amplitude and AM-to-PM distortion of a phase output signal with the addition of the auxiliary DAC circuit.

FIG. 13A shows a change in amplitude of a phase output signal for each code. The amplitude when the auxiliary DAC circuit 140 is present is indicated by black dots, and a amplitude variation is 8.1%. The amplitude without the auxiliary DAC circuit 140 is indicated by small circles, and an amplitude variation is 29.3%. In other words, it can be seen that the amplitude variation is reduced to 1/3 or less by the auxiliary DAC circuit 140.

FIG. 13B is a graph showing the degree of AM-to-PM distortion according to a phase output signal for each code. The AM-to-PM distortion when the auxiliary DAC circuit 140 is present is indicated by black dots, and the AM-to-PM distortion is 0.76 ps. The AM-to-PM distortion without the auxiliary DAC circuit 140 is indicated by small circles, and the AM-to-PM distortion is 6.42 ps. In other words, it can be seen that AM-to-PM distortion is reduced to 81.2% or less by the auxiliary DAC circuit 140. The unit “ps” stands for pico-second. When the frequency of the phase signal is 3.6 GHz, one cycle is 277.7 ps, and when interpolated at 1/64 intervals according to 64 codes, 1-step is 4.34 ps. When the AM-to-PM distortion of 0.76 ps with the auxiliary DAC circuit 140 is quantified in 1-step, it is 0.18 LSB (=0.76 ps/4.34 ps), and when the AM-to-PM distortion of 6.42 ps without the auxiliary DAC circuit 140 is quantized, it is 1.48 LSB (=6.42 ps/4.34 ps).

In this manner, some embodiments may minimize phase and amplitude variations between an output current generated by the existing phase interpolator and a target current. The reduction in amplitude variation by the current mode phase interpolator, according to some embodiments, may reduce the AM-to-PM distortion variation occurring in the output buffer of the RCD by approximately 81.2%. Through improvement enhances the linear characteristics of the RCD.

The current mode phase interpolator according to an embodiment may support a wide frequency band and improves integral non-linearity (INL), an indicator of linear characteristics, by 1.95 times from 2.06 LSB to 1.06 LSB based on actual measurements. This enhancement allows the current mode phase interpolator to outperform traditional model, which use eight phase inputs, by using only four phase inputs of I, /I, Q, and/Q. In addition, the current mode phase interpolator according to some embodiments further includes only auxiliary DAC circuits and does not include additional circuits. Accordingly, the area and power consumption of the current mode phase interpolator may be minimized.

While the disclosure has been described in connection with specific embodiments, it is to be understood that the disclosure is not limited to the disclosed embodiments. On the contrary, the disclosure is intended to cover various modifications and equivalent arrangements that fall within the spirit and scope of the appended claims.

What is claimed is:

1. A phase interpolator providing a pair of differential outputs according to a plurality of inputs with a plurality of phases, the phase interpolator comprising:
a main digital-to-analog converter (DAC) circuit configured to phase-interpolate a first input and a second input, which have orthogonal phases among the plurality of inputs, according to a main code to generate a main output signal;
an auxiliary DAC circuit configured to phase-interpolate the first input and the second input according to an auxiliary code corresponding to the main code to generate an auxiliary output signal; and
an output buffer configured to generate the pair of differential outputs according to a differential input based on a phase output signal, which is the sum of the main output signal and the auxiliary output signal.

2. The phase interpolator of claim 1, wherein:
the main DAC circuit includes
a plurality of first DACs configured to generate a plurality of phase currents based on one of the first input and the second input according to a plurality of main control signals based on the main code, and
the main code includes information on a number of DACs based on the first input and a number of DACs based the second input, among the plurality of first DACs.

3. The phase interpolator of claim 2, wherein:
each of the plurality of first DACs includes:
a bias current source;
a first transconductance stage configured to control a transconductance based on the first input;
a second transconductance stage configured to control a transconductance based on the second input;
a first switch connected between the first transconductance stage and the bias current source and configured to switch based on a first main control signal among the plurality of main control signals; and
a second switch connected between the second transconductance stage and the bias current source and configured to switch based on a second main control signal among the plurality of main control signals, and
wherein a phase current of each of the plurality of first DACs includes
a phase current flowing through the first transconductance stage and a phase current flowing through the second transconductance stage.

4. The phase interpolator of claim 3, wherein:
the first transconductance stage includes:
a first transistor including a gate to which the first input is provided, a first end connected to a first end of the first switch, and a second end connected to a first node; and
a second transistor including a gate to which a first inverted input having an inverted phase with respect to the first input is provided, a first end connected to the first end of the first switch, and a second end connected to a second node, and
wherein the second transconductance stage includes:
a third transistor including a gate to which the second input is provided, a first end connected to a first end of the second switch, and a second end connected to the first node; and
a fourth transistor including a gate to which a second inverted input having an inverted phase with respect to the second input is provided, a first end connected to the end of the second switch, and a second end connected to the second node.

5. The phase interpolator of claim 4, wherein:
each of the plurality of first DACs includes:
a fifth transistor including a gate connected to the gate of the first transistor and a source and drain connected to each other;
a sixth transistor including a gate connected to the gate of the second transistor and a source and drain connected to each other;
a third switch connected between the source and drain of the fifth transistor and the source and drain of the sixth transistor;
a seventh transistor including a gate connected to the gate of the third transistor and a source and drain connected to each other;
an eighth transistor including a gate connected to the gate of the fourth transistor and a source and drain connected to each other; and
a fourth switch connected between the source and drain of the seventh transistor and the source and drain of the eighth transistor,
wherein the third switch is turned on when the first switch is turned off, and the fourth switch is turned on when the second switch is turned off.

6. The phase interpolator of claim 3, further comprising:
a main DAC controller configured to generate each of a plurality of first main control signals and a plurality of second main control signals for each of the plurality of first DACs based on the main code,
wherein, in each of the plurality of first DACs,
when the first switch is turned on based on each of the plurality of first main control signals, the second switch is turned off based on each of the plurality of second main control signals, and
when the first switch is turned off based on each of the plurality of first main control signals, the second switch is turned on based on each of the plurality of second main control signals.

7. The phase interpolator of claim 1, wherein:
the auxiliary DAC circuit includes
a plurality of second DACs configured to generate a plurality of phase currents based on the first input and the second input according to a plurality of auxiliary control signals based on the auxiliary code, and
the auxiliary code includes information on the number of DACs based on the first input and the second input, among the plurality of second DACs.

8. The phase interpolator of claim 7, wherein:
each of the plurality of second DACs includes:
a first bias current source and a second bias current source;
a first transconductance stage configured to control a transconductance based on the first input;
a second transconductance stage configured to control a transconductance based on the second input;
a first switch connected between the first transconductance stage and the first bias current source and configured to switch based on a first auxiliary control signal among the plurality of auxiliary control signals; and
a second switch connected between the second transconductance stage and the second bias current source and configured to switch based on the first auxiliary control signal, and
wherein a phase current of each of the plurality of second DACs includes
a phase current flowing through the first transconductance stage and a phase current flowing through the second transconductance stage.

9. The phase interpolator of claim 8, wherein:
the first transconductance stage includes:
a first transistor including a gate to which the first input is provided, a first end connected to a first end of the first switch, and a second end connected to a first node; and
a second transistor including a gate to which a first inverted input having an inverted phase with respect to the first input is provided, a first end connected to the first end of the first switch, and a second end connected to a second node, and
the second transconductance stage includes:
a third transistor including a gate to which the second input is provided, a first end connected to a first end of the second switch, and a second end connected to the first node; and
a fourth transistor including a gate to which a second inverted input having an inverted phase with respect to the second input is provided, a first end connected to the first end of the second switch, and a second end connected to the second node.

10. The phase interpolator of claim 8, further comprising:
an auxiliary DAC controller configured to generate each of a plurality of auxiliary control signals for each of the plurality of second DACs based on the auxiliary code,
wherein, in each of the plurality of second DACs,
a switching operation of each of the first switch and the second switch is controlled based on each of the plurality of auxiliary control signals.

11. The phase interpolator of claim 1, wherein:
the auxiliary DAC circuit includes
a plurality of second DACs configured to generate a plurality of phase currents based on one of the first input and the second input according to a plurality of auxiliary control signals based on the auxiliary code, and
the auxiliary code includes information on a number of DACs according to the first input and a number of DACs according to the second input, among the plurality of second DACs.

12. The phase interpolator of claim 1, wherein:
the auxiliary DAC circuit generates
the auxiliary output signal with a large amplitude based on the auxiliary code when a phase of the main output signal based on the main code is in close proximity to a middle phase between a first phase corresponding to the first input and a second phase corresponding to the second input.

13. A phase interpolator comprising:
a main digital-to-analog converter (DAC) circuit configured to provide, to a first node, a first phase current based on a first input with a first weight and a second phase current based on a second input, orthogonal to the first input, with a second weight;
an auxiliary DAC circuit configured to provide a third phase current based on the first input and a fourth phase current based on the second input, with a third weight, to the first node;
an output buffer configured to generate an output signal based on a voltage of the first node; and
an auxiliary DAC controller configured to determine the third weight based on an auxiliary code that corresponds to a main code indicating the first weight and the second weight.

14. The phase interpolator of claim 13, wherein:
the auxiliary DAC controller
determines the third weight to have a large value based on the auxiliary code when phase interpolation, based on the main code, is close to a midpoint between the first phase and the second phase in a phase region between a first phase corresponding to the first input and a second phase corresponding to the second input.

15. The phase interpolator of claim 14, wherein:
the auxiliary DAC circuit includes a plurality of second DACs, and
a number of second DACs having the third weight, among the plurality of second DACs, provides the third phase current and the fourth phase current.

16. The phase interpolator of claim 13, further comprising:
a main DAC controller determining a first phase corresponding to the first input and a second phase corresponding to the second input based on the main code and determining the first weight and the second weight based on the main code.

17. The phase interpolator of claim 16, wherein:
the main DAC circuit includes a plurality of first DAC,
wherein each of a number of first DACs having the first weight, among the plurality of first DACs, provides the first phase current, and each of a number of first DACs having the second weight, among the plurality of first DACs, provides the second phase current.

18. A memory device comprising:
a plurality of memory modules; and
a phase interpolator configured to buffer a command, an address, and a clock signal provided from an external source and transmit the buffered command, address, and clock signal to the plurality of memory modules,
wherein the phase interpolator comprises:
a main digital-to-analog converter (DAC) circuit configured to phase-interpolate a first input and a second input, which have orthogonal phases, representing each of the command, the address, and the clock signal based on a main code to generate a main output signal;
an auxiliary DAC circuit configured to phase-interpolate the first input and the second input based on an auxiliary code corresponding to the main code to generate an auxiliary output signal; and
an output buffer generating a pair of differential outputs according to a differential input based on a phase output signal, which is the sum of the main output signal and the auxiliary output signal.

19. The memory device of claim 18, wherein:
the auxiliary DAC circuit includes
a plurality of second DACs configured to generate a plurality of phase currents based on the first input and the second input according to a plurality of auxiliary control signals based on the auxiliary code, and
the auxiliary code includes information about the number of DACs based on the first input and the second input, among the plurality of second DACs.

20. The memory device of claim 18, wherein:
the auxiliary DAC circuit includes
a plurality of second DACs configured to generate a plurality of phase currents based on the first input or the second input according to a plurality of auxiliary control signals based on the auxiliary code, and
the auxiliary code includes information about a number of DACs corresponding to the first input and a number of DACs corresponding to the second input, among the plurality of second DACs.
